(19) United States
(12) Patent Application Publication
(10) Pub. No.: US 2014/0051253 A1
(43) Pub. Date: Feb. 20, 2014

(54) PLASMA BAFFLE RING FOR A PLASMA PROCESSING APPARATUS AND METHOD OF USE

(71) Applicant: Joydeep Guha, Fremont, CA (US)

(72) Inventor: Joydeep Guha, Fremont, CA (US)

(73) Assignee: Lam Research Corporation, Fremont, CA (US)

(21) Appl. No.: 13/584,996

(22) Filed: Aug. 14, 2012

(51) Int. Cl. F15D 1/00; H01L 21/3065

(52) U.S. Cl. 438/710; 156/345.33; 137/803; 257/E21.218

(57) ABSTRACT

A plasma processing apparatus includes a baffle ring which separates an internal space of a vacuum chamber into a plasma space and an exhaust space. Plasma is generated in the plasma space by exciting a process gas using an energy source. The process gas is then exhausted out of the plasma space through the plasma baffle ring which surrounds an outer periphery of a substrate support. The plasma baffle ring comprises an inner support ring, an outer support ring, and vertically spaced apart circumferentially overlapping rectangular blades extending between the inner ring and the outer ring. Each blade has a major surface used to block a line of sight from the plasma space to the exhaust space, wherein the major surfaces of the blades are configured to capture nonvolatile by-products, such as plasma etch by-products, before the by-products evacuate the plasma space.

### FIELD OF THE INVENTION

The present invention relates to plasma processes of semiconductor substrates. More particularly, the present invention relates to a baffle ring and method for trapping nonvolatile by-products released during the plasma process.

### BACKGROUND

Integrated circuits are formed from a wafer or semiconductor substrate over which are formed patterned microelectronics layers. In the processing of the substrate, plasma is often employed to deposit films on the substrate or to etch intended portions of the films. Shrinking feature sizes and implementation of new materials in next generation microelectronics layers have put new requirements on plasma processing equipment. The smaller features, larger substrate size and new processing techniques require improvement in plasma processing apparatuses to control the conditions of the plasma processing.

### SUMMARY

Disclosed herein is a plasma baffle ring of a plasma processing apparatus which performs a plasma process on a semiconductor substrate. The plasma processing apparatus comprises a vacuum chamber into and from which the semiconductor substrate is loaded and unloaded. The semiconductor substrate is supported by a substrate support located within the vacuum chamber and the semiconductor substrate is supported on a top surface of the substrate support. A process gas is introduced into the vacuum chamber and is excited into plasma by an energy source and the process gas is exhausted out of the vacuum chamber through a gas exhaust port by a vacuum pump. The plasma baffle ring surrounds an outer periphery of the substrate support and is disposed in its entirety at or below a top surface of the semiconductor substrate partitioning the internal space of the vacuum chamber into a plasma space above the plasma baffle ring and an exhaust space below the plasma baffle ring. The plasma baffle ring comprises an inner support ring and an outer support ring wherein vertically spaced apart circumferentially overlapping rectangular blades are disposed between the inner support ring and the outer support ring. Each spaced apart overlapping blade has a major surface area and the spaced apart overlapping blades block a line of sight from the plasma space to the exhaust space wherein the blades are configured to capture by-products such as nonvolatile etch by-products before the by-products are evacuated from the plasma space and enter the exhaust space.

Also disclosed herein is a plasma processing method for performing a plasma process on a semiconductor substrate. The method comprises introducing a process gas into a vacuum chamber wherein the semiconductor substrate is supported on a substrate support. Plasma is generated by exciting the process gas in the vacuum chamber using an energy source. The semiconductor substrate is processed with the plasma, and by-products of the plasma process are removed from the vacuum chamber through a gas exhaust port. Before exiting the chamber, the process gas and by-products pass through a plasma baffle ring having spaced apart overlapping rectangular blades that have a major surface configured to capture nonvolatile by-products. The plasma baffle ring surrounds the substrate support and partitions the internal space of the vacuum chamber into a plasma process space and an exhaust space.

### BRIEF DESCRIPTION OF THE DRAWING FIGURES

FIG. 1 illustrates an inductively coupled plasma processing apparatus which may be used in accordance with a preferred embodiment discussed herein.

FIGS. 2A-C illustrate an embodiment of a plasma baffle ring having spaced apart overlapping blades arranged at an oblique angle relative to a top surface of a semiconductor substrate to be processed.

FIGS. 3A-3C illustrate an alternate embodiment of the plasma baffle ring having spaced apart overlapping blades which have major surfaces in vertically offset planes parallel to a top surface of a semiconductor substrate to be processed.

### DETAILED DESCRIPTION

Embodiments of the plasma baffle ring of a plasma processing apparatus will now be described in detail with reference to a few preferred embodiments thereof as illustrated in the accompanying drawings. In the following description, numerous specific details are set forth in order to provide a thorough understanding of the embodiments disclosed herein. It will be apparent, however, to one skilled in the art, that the embodiments disclosed herein may be practiced without some or all of these specific details. In other instances, well known process steps have not been described in detail in order not to unnecessarily obscure the embodiments of the plasma baffle ring of the plasma processing apparatus disclosed herein.

Disclosed herein is a plasma processing apparatus for performing a plasma process on a semiconductor substrate. In an embodiment, the plasma processing apparatus is an inductively coupled plasma processing apparatus. In an alternate embodiment the plasma processing apparatus is a capacitively coupled plasma processing apparatus. The plasma processing apparatus comprises a vacuum chamber wherein a single semiconductor substrate is supported on a top surface of a substrate support. A process gas supply delivers process gas into the vacuum chamber and the gas is excited into plasma by an energy source. The process gas is exhausted out of the vacuum chamber through at least one gas exhaust port by a vacuum pumping arrangement. A plasma baffle ring is disposed in the vacuum chamber separating the vacuum chamber into a plasma space and an exhaust space.

New integration schemes in plasma processing are introducing additional materials to enhance device performance and increase the functional density of the device. Nonvolatile plasma reaction by-product materials such as Co, Fe, Pd, Pt, Ir, Ru, Sr, Ta, Ni, Al, Mg, Mn, Ca, Ti, and alloys and oxides of the aforementioned materials are particularly useful for memory applications and are being integrated into semiconductor substrates. During plasma processing such as plasma etching, these nonvolatile etch materials are removed from the semiconductor substrate and may dissociate as they enter the plasma to form by-products gases. The by-product gases may reform into nonvolatile etch by-products at cooler temperatures wherein the nonvolatile etch by-products have properties which cause them to stick to surfaces of the vacuum chamber. During exhaustion of by-product gases, the nonvolatile etch by-products or other plasma process by-products may enter the vacuum pump or vacuum pump line which may result in improper functioning of the vacuum pump.

In accordance with an embodiment, the plasma baffle ring is dimensioned to permit by-product gases produced during processing such as plasma etching, to pass from the plasma space to the exhaust space while capturing nonvolatile by-products before they may be evacuated from the plasma space to the exhaust space. Additionally the plasma baffle ring confines the plasma within a volume defined by the plasma space. By confining the plasma inside the plasma space during plasma etch processes, a more uniform etch can be achieved, wherein the center and the edge of the substrate have substantially the same etch rates.

In another embodiment, the plasma baffle ring is placed at a location inside the vacuum chamber wherein it can exhaust process gas and reaction by-products efficiently without causing contamination of the substrate. Particle contamination can be created by the disturbance of flow of the exhausted gas and by-products and therefore placement in a location which does not cause turbulence in gas flow can reduce particulate contamination.

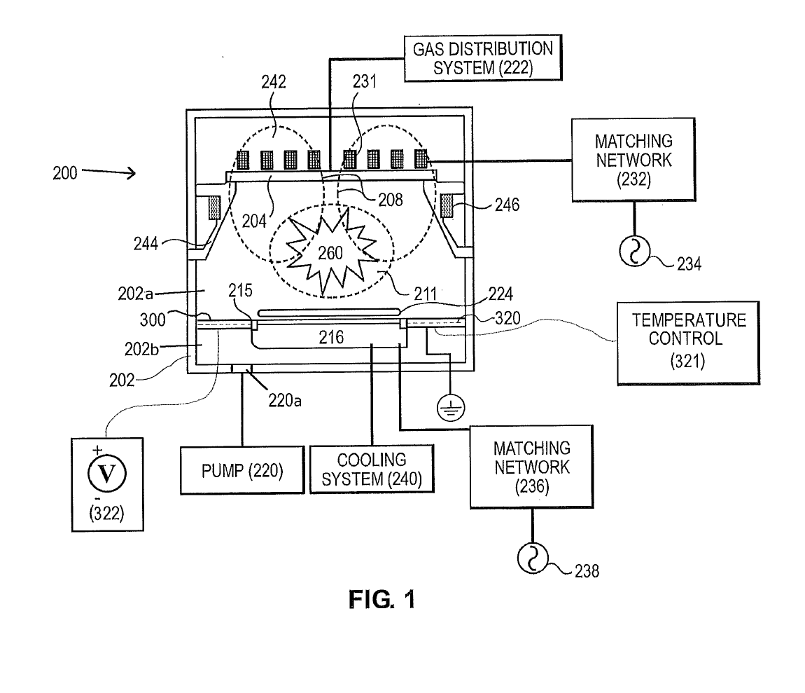

FIG. 1 illustrates an inductively coupled plasma processing apparatus 200 which may be used in accordance with a preferred embodiment discussed herein. The inductively coupled plasma processing apparatus 200 includes a vacuum chamber 202 having a plasma space 202a and an exhaust space 202b. Process gas is supplied into plasma space 202a from gas distribution system 222. The process gas may be subsequently ionized to form a plasma 260, in order to process (e.g., etching or deposition) exposed areas of semiconductor substrate 224, such as a semiconductor substrate or a glass pane, supported on a substrate support 216 with an edge ring 215 located on an outer periphery of the substrate support 216. Details of an exemplary gas distribution system may be found in commonly-owned U.S. Pat. No. 8,133,349, the disclosure of which is hereby incorporated by reference. Plasma etching gases may include C₄F₈, C₄F₆, CHF₃, CH₂F₃, CF₄, HBr, CH₃F, C₂F₄, N₂, O₂, Ar, Xe, He, H₂, NH₃, SF₆, BCl₃, Cl₂, NF₃, PF₃, COF₂, NO, SO₂ and combinations thereof.

Induction coil 231 is separated from the plasma space 202a of the vacuum chamber 202 by a dielectric window 204 forming the upper wall of the vacuum chamber 202, and generally induces a time-varying electric current in the plasma processing gases to create plasma 260. The dielectric window 204 both protects induction coil 231 from plasma 260, and allows the generated RF field 208 to generate an inductive current 211 within the vacuum chamber 200. Further coupled to induction coil 231 is matching network 232 coupled to RF generator 234. The RF generator 234 supplies RF current preferably at a range of about 100 kHz-100 MHz, and more preferably at 13.56 MHz. Matching network 232 attempts to match the impedance of RF generator 234 to that of the plasma 260 (typically operating at about 13.56 MHz and about 50 ohms). Additionally, a second RF energy source 238 may also be coupled through matching network 236 to a bottom electrode (not shown) in substrate support 216 in order to apply an RF bias to the substrate 224 (e.g., 2 MHz, 13.56 MHz, 400 kHz). Gases and by-products are removed from the vacuum chamber by a vacuum pump 220 through a gas exhaust port 220a.

A plasma baffle ring 300 surrounds and is disposed outside of the outer periphery of the substrate support 216. The plasma baffle ring 300 is disposed in its entirety at or below a top surface of the semiconductor substrate 224 partitioning the internal space of the vacuum chamber 202 into plasma space 202a and exhaust space 202b. The plasma baffle ring 300 is configured to control gas flow conductance between the plasma space 202a and the exhaust space 202b. Additionally, the plasma baffle ring is dimensioned to permit by-product gases, during processing, to pass from the plasma space 202a to the exhaust space 202b while capturing by-products such as nonvolatile by-products before reaching the exhaust space 202b.

Preferably, the plasma baffle ring 300 is electrically grounded and substantially fills the annular space between an inside periphery of a wall of the vacuum chamber 202 or an optional shroud (not shown), and the outer periphery of the substrate support to allow substantially all the exhaust gases to pass through the plasma baffle ring 300. The optional shroud can be used to line the interior of the chamber wherein the shroud may be configured to contact the plasma baffle ring 300 forming a floating ground. The optional shroud may prevent the plasma from grounding through the chamber walls and also may confine the plasma to a specific volume inside the chamber. Details of an exemplary shroud and a perforated plasma baffle ring assembly may be found in commonly-owned U.S. Pat. No. 6,178,919, the disclosure of which is hereby incorporated by reference.

The plasma baffle ring 300 is preferably formed from an electrically conductive material that is also substantially resistant to etching by a plasma within the vacuum chamber during the processing of substrate 224. For example the plasma baffle ring 300 may be formed from anodized aluminum and may preferably comprise an outer coating, such as yttrium oxide, which can increase the adhesion of reaction by-products such as nonvolatile etch by-products. The outer periphery of the substrate support 216 may optionally include the edge ring 215. The inner periphery of the perforated plasma baffle ring 300 is preferably dimensioned to fit around the substrate support 216 or the plasma baffle ring 300 can be separated from the substrate support 216 by a narrow gap which keeps the plasma substantially confined.

In one embodiment, the plasma baffle ring 300 is placed at a location inside the vacuum chamber 202 wherein it can exhaust by-product gases efficiently without causing contamination of the semiconductor substrate 224. Structures that are placed above the substrate 224 during processing tend to cause contamination of the substrate 224. This is because such structures may present sites or surfaces for adsorbed materials to attach. Over time, the adsorbed materials may flake off onto the substrate 224, causing particulate contamination. Therefore, the placement of the plasma baffle ring 300 is preferably downstream from the substrate 224.

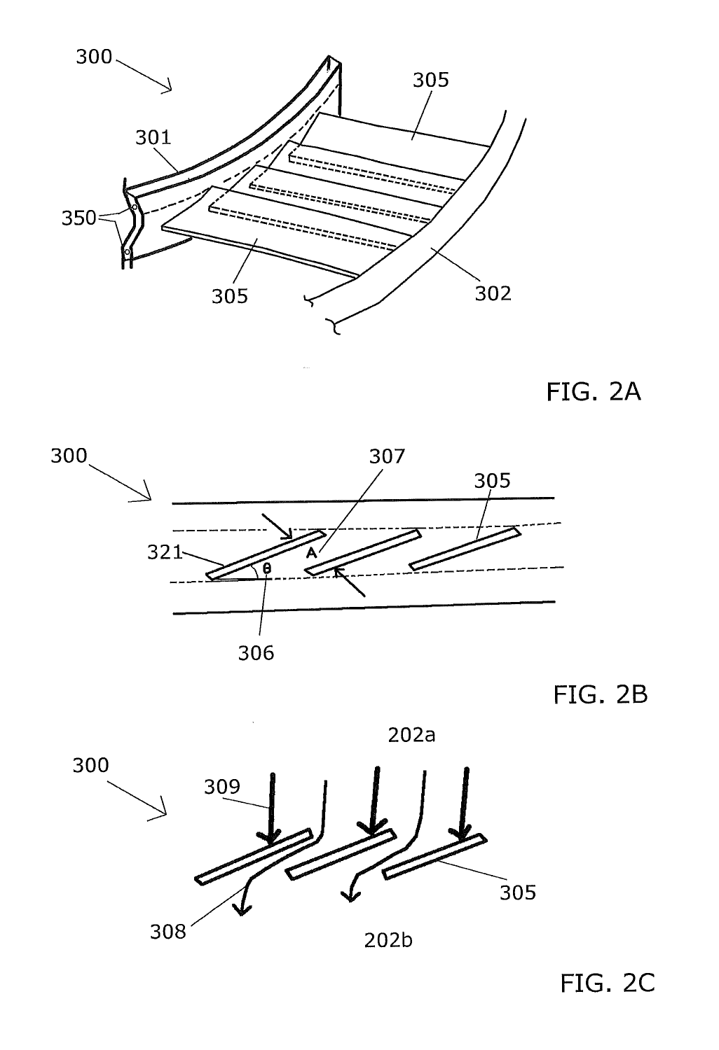

The plasma baffle ring 300 is optionally temperature controlled by a thermal control mechanism 331. The plasma baffle ring 300 may include a heater 320, such as resistance heater wire disposed in the inner and/or outer support rings 301, 302 of the plasma baffle ring, or the resistance heater wire may be located in the vertically spaced apart circumferentially overlapping blades of the plasma baffle ring 300 as well as in the inner and/or outer support rings 301, 302. In an alternative embodiment, the heater may be an infrared lamp disposed at the bottom of the vacuum chamber 202. Furthermore the plasma baffle ring 300 may include internal flow passages 350 (See FIG. 2A) disposed in the inner support ring 301 or in an alternate embodiment the internal flow passages 350 may be disposed in inner and outer support rings 301, 302 of the plasma baffle ring, wherein a chiller pumps a coolant therethrough in order to cool the plasma baffle ring 300. In a further embodiment the flow passages 340 may be located in the vertically spaced apart circumferentially overlapping blades of the plasma baffle ring 300 as well as in the inner and/or outer support rings 301, 302.

Generally, a cooling system 240 is coupled to substrate support 216 in order to maintain the semiconductor substrate 224 at a desired temperature. The cooling system itself is usually comprised of a chiller that pumps a coolant through flow passages within the substrate support 216, and a heat transfer gas such as helium is pumped between the substrate support 216 and the semiconductor substrate 224 to control thermal conductance between the semiconductor substrate 224 and the substrate support 216. Increasing helium pressure increases the heat transfer rate and decreasing helium pressure reduces heat transfer. In addition, the substrate support may include heaters for adjusting the temperature of the substrate during processing.

In addition, a temperature control apparatus 246 may operate to control the temperature of an upper chamber section 244 of the plasma processing apparatus 200 such that the inner surface of the upper chamber section 244, which is exposed to the plasma during operation, is maintained at a controlled temperature.

The upper chamber section 244 can be a machined piece of aluminum or hard anodized aluminum which can be removed for cleaning or replacement thereof. The inner surface of the upper chamber section 244 is preferably anodized aluminum or a plasma resistant material such as a thermally sprayed yttria coating.

FIGS. 2A-C illustrate an embodiment of the plasma baffle ring 300. FIG. 2A shows a segment of the plasma baffle ring 300 which comprises an inner support ring 301 and an outer support ring 302. Vertically spaced apart circumferentially overlapping planar blades 305 are disposed between the inner support ring 301 and the outer support ring 302. The blades 305 are rectangular and arranged in a radial pattern wherein each blade extends radially between the inner and outer support rings 301, 302 and each blade is angled such that the major surface of the blade forms an acute angle with a plane parallel to the support surface. The blades 305 are spaced vertically apart and overlap such that an upper end portion of each blade 305 overlaps a lower end portion of each adjacent blade 305. The overlapping blades 305 are each oriented at an oblique angle of 1 to 60°, preferably 10 to 45°, with respect to the top surface of the substrate support. Additionally, each blade 305 has a major surface facing the plasma space 202a and is configured to capture by-products such as nonvolatile etch by-products before the nonvolatile by-products enter the exhaust space 202b.

FIG. 2B illustrates a cross section of the plasma baffle ring 300. The blades 305 each have an upward tilt angle 306 along the circumferential direction of the plasma baffle ring 300 and adjacent blades 305 are spaced apart by a gap 307. By adjusting the upward tilt angle 306 and the gap 307 the required gas conductance of the plasma processing apparatus may be controlled. In a preferred embodiment the blades 305 may be fixed at a predetermined upward tilt angle 306, or in an alternative embodiment the blades 305 may be configured to be rotatable such that the upward tilt angle 306 may be mechanically adjusted.

Preferably, the blades 305 have a roughened surface coating 321. The roughened surface coating 321 increases the surface area of the major surface of the blades 305 increasing the capture rate of the by-products such as nonvolatile by-products. The surface coating is preferably a plasma sprayed yttrium oxide layer or other suitable coating material.

FIG. 2C shows a schematic of the plasma baffle ring 300 obstructing nonvolatile by-products 309 and allowing transport of reaction by-product gases 308 therethrough. The plasma baffle ring 300 is configured to partition the internal space of the vacuum chamber 202 into the plasma space 202a and the exhaust space 202b. The major surface area of the blades 305 permits by-product gases 308, during processing, to pass from the plasma space 202a to the exhaust space 202b while capturing nonvolatile by-products 309 before they enter the exhaust space 202b.

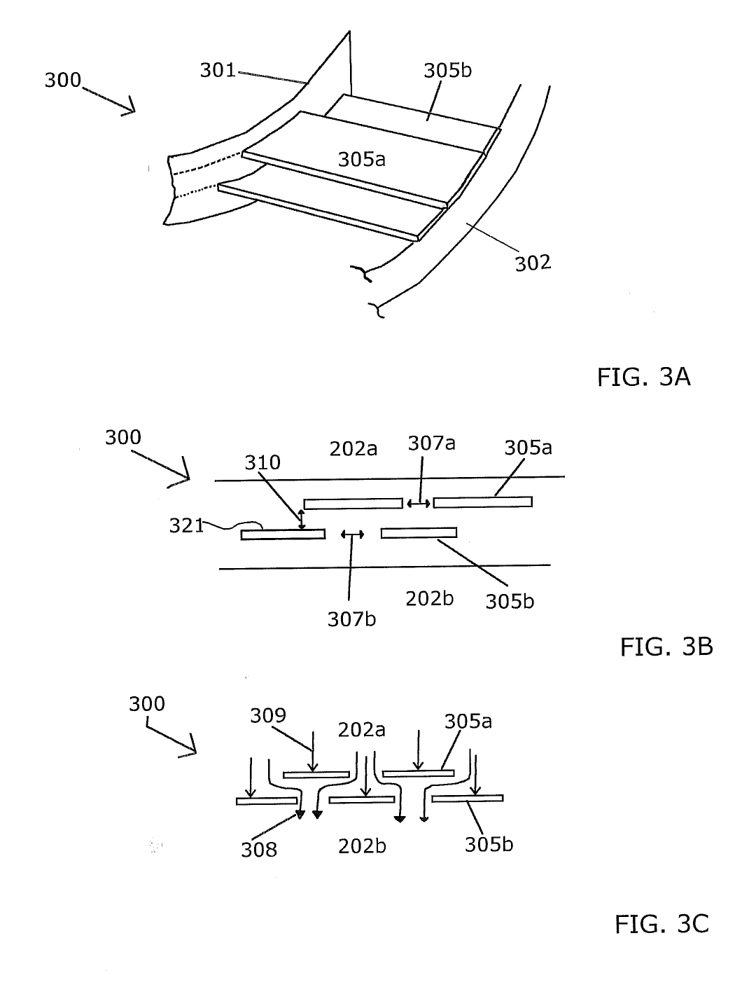

FIGS. 3A-3C illustrate an alternate embodiment of the plasma baffle ring 300. FIG. 3A shows a segment of the plasma baffle ring 300 which comprises an inner support ring 301 and an outer support ring 302. Vertically spaced apart and overlapping blades 305a, b (herein 305) are disposed between the inner ring 301 and the outer ring 302. The blades 305 are arranged in a radial pattern. A first upper group of spaced apart rectangular blades 305a lies in an upper plane vertically above a second lower group of spaced apart rectangular blades 305b which lie in a lower plane such that a line of sight from the plasma space to the exhaust space is blocked by the spaced apart overlapping blades 305. Additionally, each blade 305 has a major surface configured to capture nonvolatile by-products before the nonvolatile by-products enter the exhaust space.

FIG. 3B illustrates a cross section of the plasma baffle ring 300. The rectangular blades 305a, b preferably have major faces thereof and are parallel to the top surface of the substrate support (not shown). The first group of spaced apart rectangular blades 305a face the plasma space 202a and the second group of spaced apart rectangular blades 305b face the exhaust space 202b and adjacent blades 305a,b are spaced apart by horizontal gaps 307a,b. By adjusting a vertical distance 310 between blades 305a and 305b, and the spacing of gaps 307a,b the gas conductance of the plasma processing apparatus may be controlled.

Preferably, the blades 305a,b have a roughened surface coating 321. The roughened surface coating 321 increases the surface area of the major surface of the blades 305a,b increasing the capture rate of the nonvolatile by-products. The surface coating 321 is preferably a plasma sprayed yttrium oxide layer or other suitable coating material.

FIG. 3C shows a schematic of the plasma baffle ring 300 obstructing nonvolatile by-products 309 and allowing transport of by-product gases 308 therethrough. The plasma baffle ring 300 is configured to partition the internal space of the vacuum chamber 202 into the plasma space 202a and the exhaust space 202b. Additionally, the plasma baffle ring 300 is configured to block the line of sight from plasma space 202a to exhaust space 202b. The plasma baffle ring 300 is dimensioned to permit by-product gases 308, during processing, to pass from the plasma space 202a to the exhaust space 202b while capturing nonvolatile by-products 309 before they enter the exhaust space 202b.

Referring to FIGS. 2A-C and 3A-C the plasma baffle ring 300 is preferably formed out of an electrically conductive material. More preferably the plasma baffle ring 300 is formed out of aluminum, anodized aluminum, or silicon carbide. The spaced apart overlapping blades 305 can be brazed to the inner ring 301 and the outer ring 302. Alternatively, the plasma baffle ring 300 may be machined from a single piece of aluminum.

Preferably gaps 307 should form slots between the spaced apart overlapping blades 305 and the gaps 307 should preferably be sized to allow the plasma baffle ring 300 to have high process gas conductance. While not wishing to be bound by theory, it is believed that a slot configuration will increase the process gas conductance of the plasma baffle ring 300 as opposed to alternate configurations (e.g. holes).

In a preferred embodiment, the spaced apart overlapping blades 305 of the plasma baffle ring 300 further include the thermal control mechanism 331. The thermal control mechanism 331 may control the temperature of the spaced apart overlapping blades to increase or decrease the temperature which can increase the adhesion of nonvolatile by-products. The temperature can be varied to target specific by-product materials such as nonvolatile etch by-product materials Co, Fe, Pd, Pt, Ru, Sr, Ta, Ir, Ni, Al, Mg, Mn, Ca, Ti, F, and compounds of the aforementioned materials such as AlF.

In a preferred embodiment, a predetermined voltage is applied to the spaced apart overlapping blades 305 of the plasma baffle ring 300 from a voltage source 322. The voltage is set such that a voltage potential of the major surfaces of the spaced apart overlapping rectangular blades 305 is higher than that of the plasma. The predetermined voltage can increase the adhesion of by-products, such as nonvolatile etch by-products, as well as repel charged particles which are utilized in plasma processes. As a result, an exhaust efficiency of the processing gas in the plasma space 202a can be enhanced and a leakage of plasma may be suppressed.

In accordance with embodiments of the plasma baffle ring of the plasma processing apparatus a method is provided for plasma processing a semiconductor substrate. The method comprises placing the semiconductor substrate within the vacuum chamber and introducing the process gas into the vacuum chamber. Next plasma is generated by exciting the process gas in the vacuum chamber using radio frequency energy and process gas is exhausted out of the vacuum chamber through the gas exhaust port after passing through the plasma baffle ring. The plasma baffle ring comprises an inner support ring and an outer support ring wherein vertically spaced apart circumferentially overlapping rectangular blades are disposed between the inner support ring and the outer support ring. Each spaced apart overlapping blade has a major surface area and the spaced apart overlapping blades block a line of sight from the plasma space to the exhaust space wherein the blades are configured to capture by-products such as nonvolatile etch by-products before the by-products are evacuated from the plasma space and enter the exhaust space.

In a preferred embodiment the method further comprises adjusting the temperature of the spaced apart overlapping blades to increase the capture rate of targeted nonvolatile etch by-products.

In a preferred embodiment the method further comprises applying a predetermined voltage to the spaced apart overlapping rectangular blades wherein the voltage is set such that a voltage potential of the major surfaces of the spaced apart overlapping rectangular blades is higher than that of the plasma.

Having disclosed exemplary embodiments and the best mode, modifications and variations may be made to the disclosed embodiments while remaining within the subject and spirit of the disclosed embodiments as defined by the following claims.

1. A plasma processing apparatus for performing a plasma process on a semiconductor substrate, comprising:
a vacuum chamber wherein a single semiconductor substrate can be loaded and unloaded;
a substrate support provided within the vacuum chamber such that the semiconductor substrate can be mounted on a top surface of the substrate support;
a gas injection member which supplies a process gas into the vacuum chamber;
an energy source used to excite the process gas in the vacuum chamber to generate plasma;
at least one gas exhaust port through which the process gas is exhausted out of the vacuum chamber; and
a plasma baffle ring surrounding an outer periphery of the substrate support, said plasma baffle ring being disposed at or below a top surface of the semiconductor substrate and partitioning an internal space of the vacuum chamber into a plasma space above the plasma baffle ring and an exhaust space below the plasma baffle ring, the plasma baffle ring comprising an inner support ring and an outer support ring and vertically spaced apart circumferentially overlapping rectangular blades extending between the inner ring and the outer ring, each blade having a major surface and the spaced apart overlapping blades blocking a line of sight from the plasma space to the exhaust space, the major surfaces of the blades configured to capture nonvolatile by-products before the by-products evacuate the plasma space and enter the exhaust space.

2. The plasma processing apparatus of claim 1, wherein the vertically spaced apart circumferentially overlapping blades further include a thermal control mechanism configured to heat or cool the blades to increase the capture rate of nonvolatile by-products.

3. The plasma processing apparatus of claim 1, wherein the plasma baffle ring is electrically grounded and the spaced apart overlapping blades are electrically conductive.

4. The plasma processing apparatus of claim 1, wherein the plasma baffle ring is formed from aluminum, anodized aluminum, or silicon carbide.

5. The plasma processing apparatus of claim 1, wherein the vertically spaced apart circumferentially overlapping blades are electrically conductive and connected to a voltage source which applies voltage to the blades sufficient to maintain a voltage potential of the major surfaces of the spaced apart overlapping rectangular blades higher than that of the plasma.

6. The plasma processing apparatus of claim 1, wherein each of the blades has a roughened surface coating configured to increase the surface area of the major surface of each blade.

7. The plasma processing apparatus of claim 6, wherein the roughened surface coating is a plasma sprayed yttrium oxide.

8. The plasma processing apparatus of claim 1, wherein the blades are angled such that major surfaces of the spaced apart overlapping blades are each oriented at an oblique angle with respect to the top surface of the substrate support wherein an upper portion of each blade overlaps a lower portion of an adjacent blade and the line of sight from the plasma space to the exhaust space is blocked by the spaced apart overlapping blades.

9. The plasma processing apparatus of claim 1, wherein a first group of spaced apart rectangular blades is coplanar and form slots facing the plasma space;
a second group of spaced apart rectangular blades is coplanar and form slots facing the exhaust space;
wherein the first group of spaced apart rectangular blades overlaps the second group of spaced apart rectangular blades and the first group and second group of spaced apart rectangular blades overlap to block the line of sight from the plasma space to the exhaust space.

10. The plasma processing apparatus of claim 9, wherein major surfaces of the first and second groups of spaced apart rectangular blades are parallel to the top surface of the substrate support.

11. A plasma baffle ring of a plasma processing apparatus in which a process gas is introduced into a vacuum chamber, plasma is generated by exciting the process gas in the vacuum chamber using radio frequency energy, and the process gas is exhausted out of the vacuum chamber through a gas exhaust port, the plasma baffle ring configured to fit around an outer periphery of a substrate support which supports a semiconductor substrate to be processed and partition the internal space of the vacuum chamber into a plasma space above the plasma baffle ring and an exhaust space below the plasma baffle ring, the plasma baffle ring comprising:
an inner support ring;
an outer support ring; and
vertically spaced apart circumferentially overlapping rectangular blades extending between the inner support ring and the outer support ring, each blade has a major surface and the spaced apart overlapping blades block a line of sight from the plasma space to the exhaust space, the major surfaces of the blades are configured to capture nonvolatile by-products before the by-products evacuate the plasma space and enter the exhaust space.

12. The plasma baffle ring of claim 11, wherein the vertically spaced apart circumferentially overlapping rectangular blades further include a thermal control mechanism configured to heat or cool the blades to increase the capture rate of nonvolatile by-products.

13. The plasma baffle ring of claim 11, wherein the blades are electrically conductive.

14. The plasma baffle ring of claim 11, wherein the plasma baffle ring is formed from aluminum, anodized aluminum or silicon carbide.

15. The plasma baffle ring of claim 11, wherein each blade of the plasma baffle ring has a roughened surface coating configured to increase the surface area of the major surface of each blade.

16. The plasma baffle ring of claim 15, wherein the roughened surface coating is a plasma sprayed yttrium oxide.

17. The plasma baffle ring of claim 11, wherein the spaced apart overlapping rectangular blades are angled such that each blade is oriented at an oblique angle with respect to the top surface of the substrate support wherein an upper portion of each blade overlaps a lower portion of an adjacent blade and the line of sight from the plasma space to the exhaust space is blocked by the spaced apart overlapping blades.

18. The plasma baffle ring of claim 11, wherein a first group of spaced apart rectangular blades is coplanar and form slots in the plasma space;
a second group of spaced apart rectangular blades is coplanar and form slots in the exhaust space;
wherein the first group of spaced apart rectangular blades overlaps the second group of spaced apart rectangular blades and the first group and second group of spaced apart rectangular blades overlap to block the line of sight from the plasma space to the exhaust space.

19. The plasma baffle ring of claim 18, wherein major surfaces of the first and second groups of spaced apart overlapping rectangular blades are parallel to the top surface of the substrate support.

20. A plasma processing method for performing a plasma process on a semiconductor substrate, comprising:
supporting a semiconductor substrate on a substrate support in a vacuum chamber;
introducing a process gas into the vacuum chamber;
generating plasma by exciting the process gas in the vacuum chamber using radio frequency energy;
exhausting the process gas out of the vacuum chamber through a gas exhaust port via a plasma baffle ring having an inner support ring, an outer support ring, and vertically spaced apart circumferentially overlapping rectangular blades extending between the inner support ring and the outer support ring, each blade has a major surface and the spaced apart overlapping blades block a line of sight from the plasma space to the exhaust space, the major surfaces of the blades are configured to capture nonvolatile by-products before the by-products evacuate the plasma space and enter the exhaust space; and
capturing nonvolatile by-products on the major surfaces of the blades of the plasma baffle ring as the process gas is exhausted therethrough.

21. The method of claim 20, wherein the process gas is a plasma etching gas, the method further comprising adjusting the temperature of the vertically spaced apart circumferentially overlapping blades to increase the capture rate of nonvolatile etch by-products.

22. The method of claim 20, wherein a predetermined voltage is applied to the spaced apart overlapping rectangular blades and the voltage is set such that a voltage potential of the major surfaces of the spaced apart overlapping rectangular blades is higher than that of the plasma.
